(19) United States
(12) Patent Application Publication
(10) Pub. No.: US 2022/0115854 A1
(43) Pub. Date: Apr. 14, 2022

(54) ELECTRICAL JUNCTION BOX

(71) Applicants: AutoNetworks Technologies, Ltd., Yokkaichi-shi, Mie (JP); Sumitomo Wiring Systems, Ltd., Yokkaichi-shi, Mie (JP); Sumitomo Electric Industries, Ltd., Osaka-shi, Osaka (JP)

(72) Inventor: Tatsuya Shimizu, Yokkaichi-shi, Mie (JP)

(21) Appl. No.: 17/421,994

(22) PCT Filed: Dec. 27, 2019
(86) PCT No.: PCT/JP2019/051414

§ 371 Date: Jul. 9, 2021

(30) Foreign Application Priority Data
Jan. 11, 2019 (JP) 2019-003777

(51) Int. Cl. H02G 3/16; H05K 1/02; H05K 9/00; H05K 7/12

(52) U.S. Cl. CPC H02G 3/16; H05K 7/12; H05K 9/003; H05K 1/0219

(57) ABSTRACT

An electrical junction box includes: a substrate unit having a circuit board on which a conductive path including a ground line is formed, a shield case for covering the circuit board, and a first fastening member for fastening the circuit board and the shield cases; a case unit having resin cases made of resin and a frame fixed to the resin case; and a second fastening member for fastening the circuit board in the substrate unit and the case unit, in which the shield case is electrically connected to the ground line by fastening the circuit board and the shield case with the first fastening member.

### CROSS-REFERENCE TO RELATED APPLICATIONS

This application is the U.S. national stage of PCT/JP2019/051414 filed on Dec. 27, 2019, which claims priority of Japanese Patent Application No. JP 2019-003777 filed on Jan. 11, 2019, the contents of which are incorporated herein.

### TECHNICAL FIELD

The present specification discloses a technique relating to an electrical junction box.

### BACKGROUND

Conventionally, an electrical junction box in which a circuit board is housed in a case has been known. JP H08-222877A includes upper and lower housings that cover a shield cover and a printed circuit board. The upper and lower housings are molded from plastic or the like, and are fitted to each other while sandwiching the printed circuit board and the shield cover therebetween, and are fastened with screws from a lower side of the lower housing. The printed circuit board includes a solid ground and a protrusion made of solder formed on a solid ground forming portion, and when the housings are fastened with the screws, the shield cover is pressed against the printed circuit board, and the solid ground on the printed circuit board and the shield cover are electrically connected to each other, whereby a region covered by the shield cover is shielded.

Incidentally, in the above configuration, in addition to fixing the upper and lower housings, the shield cover, and the printed circuit board, the shield cover and the solid ground of the printed circuit board are electrically connected by fastening with the screws. When the fixing of the upper and lower housings, the shield cover, and the printed circuit board, and the electrical connection between the shield cover and the solid ground of the printed circuit board are performed by fastening with common screws in this way, the appropriate torque when fastening the screws differs depending on whether the members are to be fixed or electrically connected, and therefore there are concerns about problems such as poor connection between the shield cover and the solid ground due to the torque being too high, and insufficient fixing strength of the upper and lower housings, the shield cover, and the printed circuit board due to the torque being too low.

The technique described in this specification has been completed based on the above circumstances, and an object of the technique is to provide an electrical junction box fastened with an appropriate torque.

### SUMMARY

The electrical junction box described in this specification includes: a substrate unit having a circuit board on which a conductive path including a ground line is formed, a shield case for covering the circuit board, and a first fastening member for fastening the circuit board and the shield case; a case unit having a resin case made of resin and a frame fixed to the resin case; and a second fastening member for fastening the circuit board in the substrate unit and the case unit, in which the shield case is electrically connected to the ground line by fastening the circuit board and the shield case with the first fastening member.

According to the above configuration, for the substrate unit, the ground line and the shield case can be electrically connected while fixing the shield case to the circuit board by fastening the circuit board and the shield case with the first fastening member. Further, the relative positions of the substrate unit and the case unit can be fixed by fastening with the second fastening member. This makes it possible to fasten the circuit board to the shield case for electrical connection and to fasten the circuit board to the case unit for fixing, with respective appropriate torques. Therefore, it is possible to provide the electrical junction box fastened with the appropriate torque.

The following aspects are preferred as embodiments of the technique described in this specification.

A third fastening member for fastening the frame and the resin case is provided, and the frame holds a power storage element.

In a state where the frame holds the power storage element, there is a concern that the weight of the power storage element may cause a problem due to stress generated, for example, at the portion fastened with the second fastening member. According to the above configuration, since the power storage element is fixed to the resin case via the frame, it is possible to suppress the problem regarding the weight of the power storage element via the frame, and to fasten the frame and the first resin case with an appropriate torque with the third fastening member.

The shield case includes a first shield case for covering one plate surface of the circuit board and a second shield case for covering the other plate surface of the circuit board.

In this way, the influence of noise can be suppressed on both sides of the circuit board.

The circuit board has a through-hole region in which a plurality of through-holes are electrically connected along an edge portion of the shield case, and the through-hole region is connected to a ground potential.

### Advantageous Effects of Invention

According to the technique described in this specification, it is possible to provide an electrical junction box fastened with an appropriate torque.

### BRIEF DESCRIPTION OF DRAWINGS

FIG. 1 is a plan view illustrating an electrical junction box of an embodiment.

FIG. 2 is a cross-sectional view taken along a line A-A of FIG. 1.

FIG. 3 is an enlarged view of a part of FIG. 2.

FIG. 4 is a cross-sectional view taken along a line B-B of FIG. 1.

FIG. 5 is a cross-sectional view taken along a line C-C of FIG. 1.

FIG. 6 is an enlarged view of a part of FIG. 5.

FIG. 7 is a cross-sectional view taken along a line D-D of FIG. 1.

FIG. 8 is an exploded perspective view of the electrical junction box.

FIG. 9 is a perspective view illustrating a step of attaching a first shield case to a first resin case.

FIG. 10 is a perspective view illustrating a step of attaching a frame to the first resin case after assembly of FIG. 9.

FIG. 11 is a perspective view illustrating a step of attaching a circuit board to the frame after assembly of FIG. 10.

FIG. 12 is a perspective view illustrating a step of attaching a second shield case to the circuit board after assembly of FIG. 11.

FIG. 13 is a perspective view illustrating the electrical junction box in a state where a second resin case after assembly of FIG. 12 is removed.

FIG. 14 is a perspective view illustrating the circuit board to which a connector of another embodiment is attached.

FIG. 15 is a vertical cross-sectional view of a middle part of the connector.

### DETAILED DESCRIPTION OF PREFERRED EMBODIMENTS

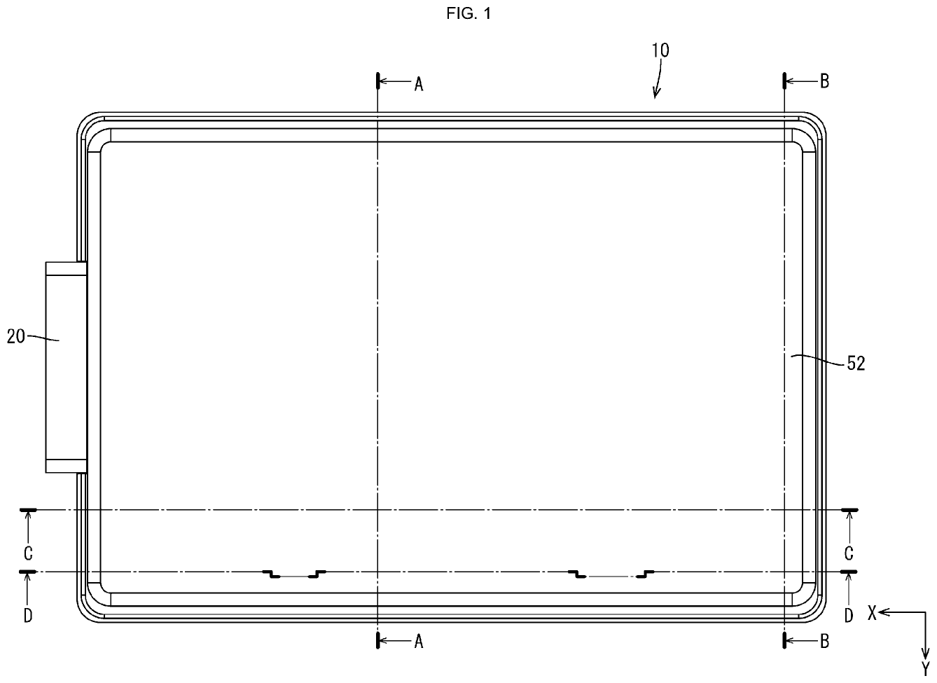

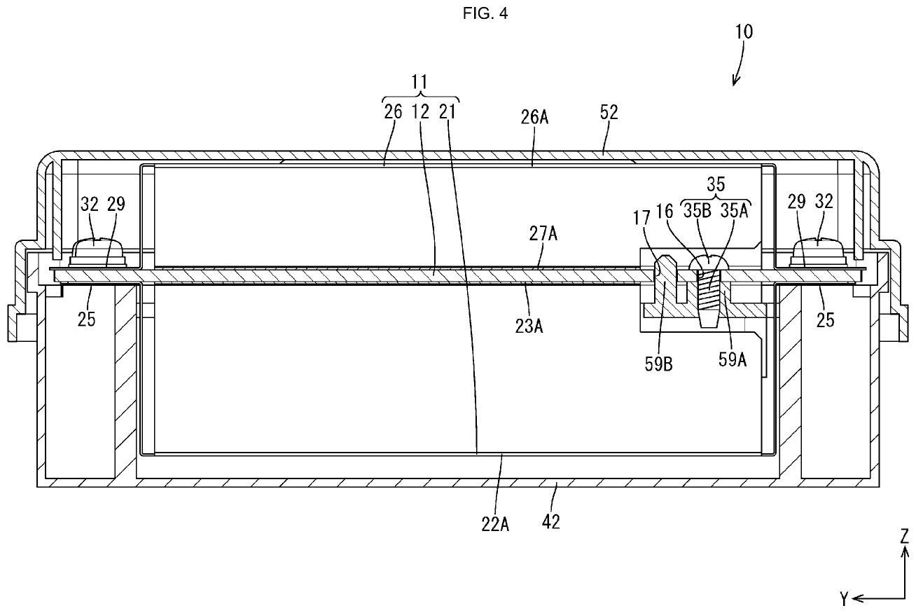

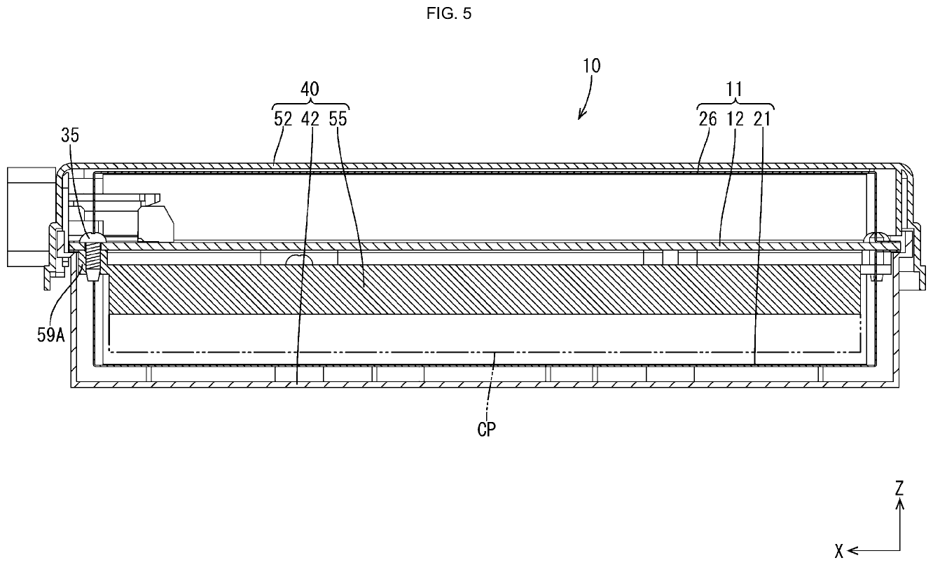

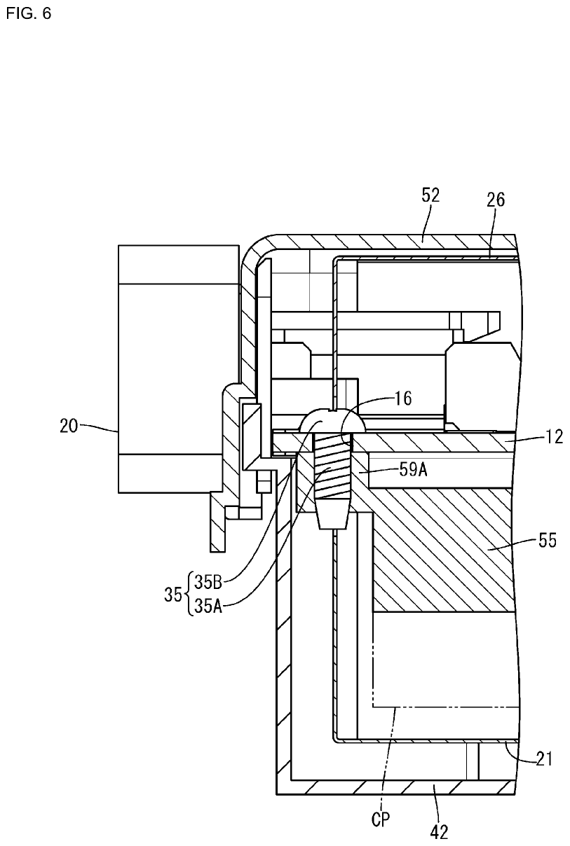

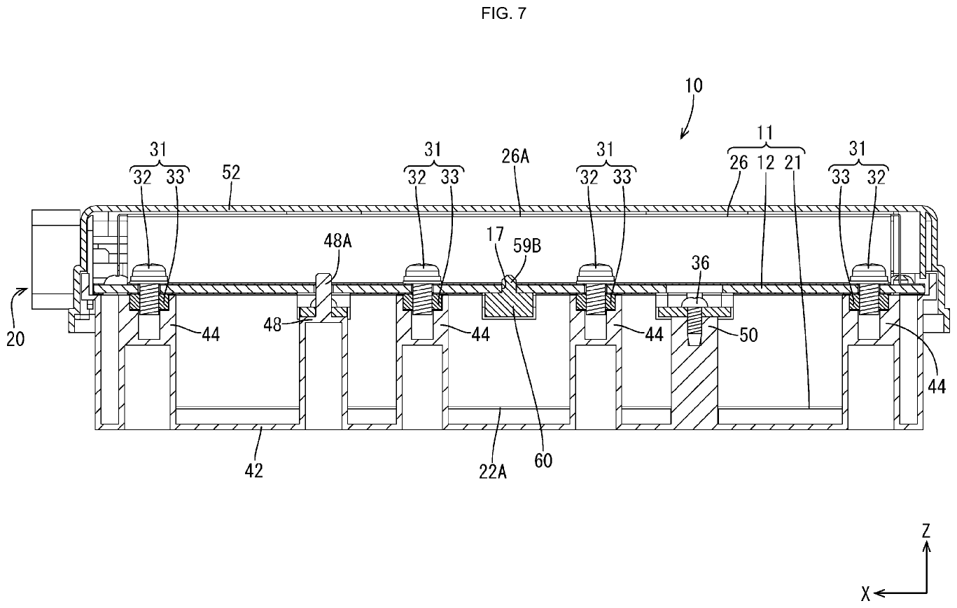

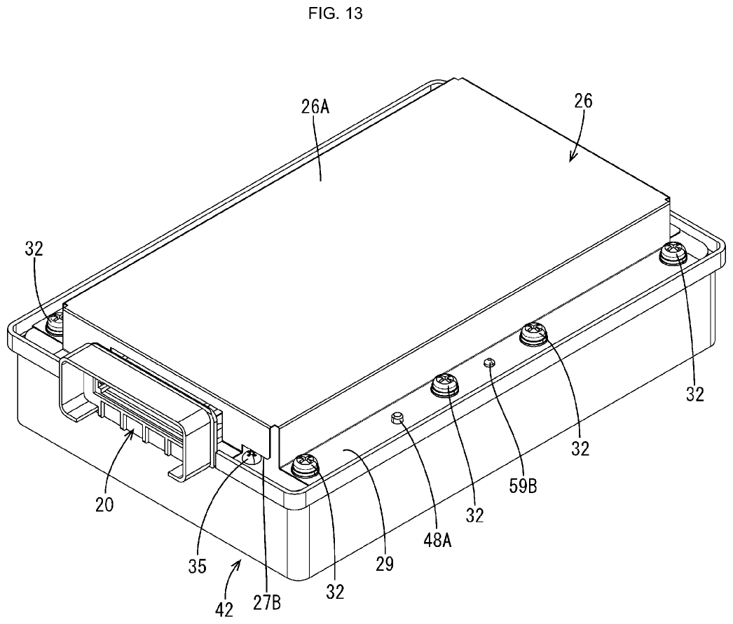

An embodiment will be described with reference to FIGS. 1 to 13.

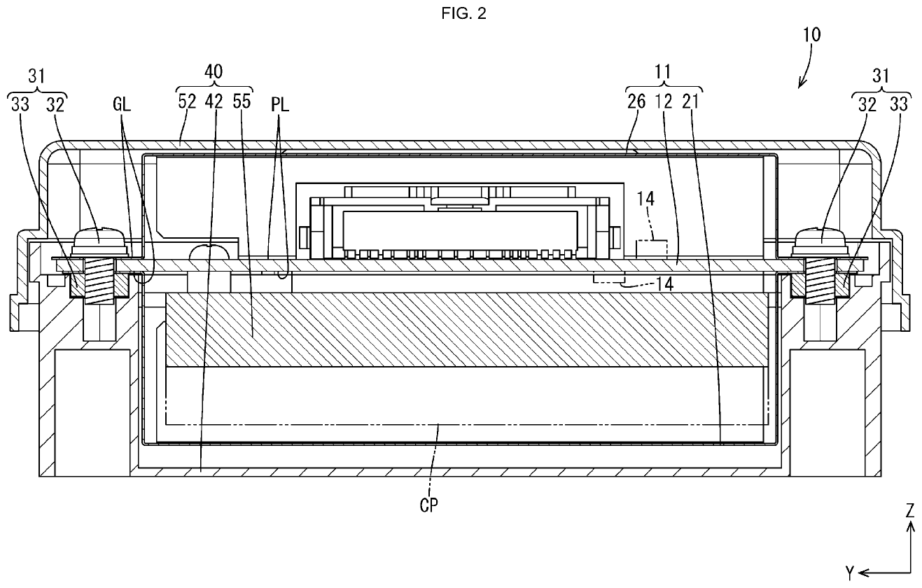

An electrical junction box 10 (FIG. 1) of the present embodiment is provided separately from a main power source for supplying a driving force of a vehicle in the vehicle such as an electric vehicle or a hybrid vehicle, and can be used as an auxiliary power source or the like that can supply electric power to an in-vehicle electrical component, a motor of a device, or the like. Hereinafter, an X direction in FIG. 1 will be described as frontward, a Y direction as left, and a Z direction in FIG. 2 as upward.

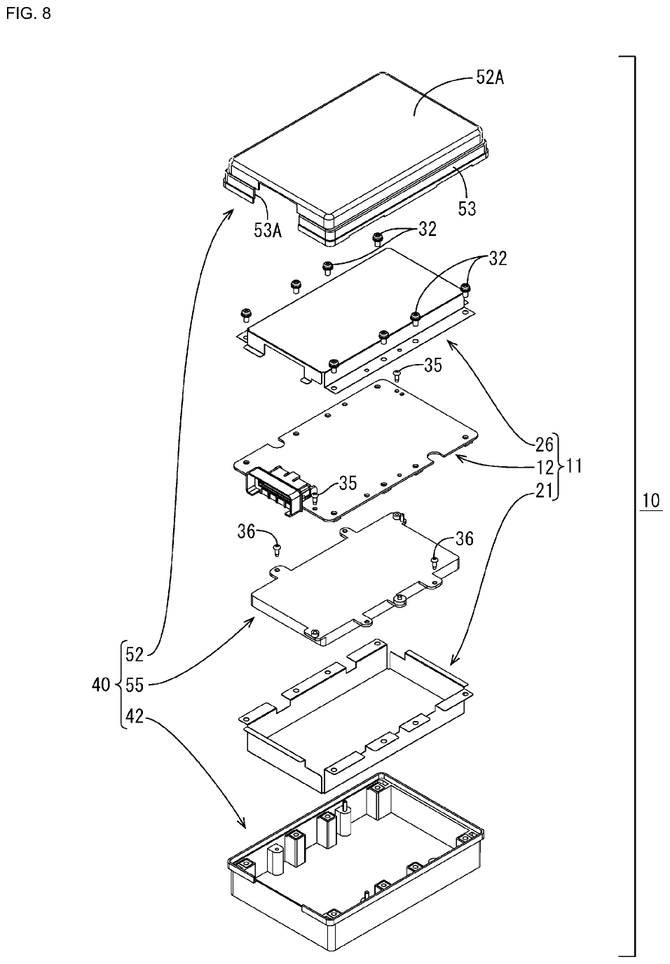

As illustrated in FIGS. 2 and 8, the electrical junction box 10 includes a substrate unit 11 and a case unit 40 having resin cases 42 and 52 and a frame 55. The substrate unit 11 includes a circuit board 12 on which a conductive path is formed, shield cases 21 and 26 for covering both sides of the circuit board 12, and a first fastening member 31 for fastening the circuit board 12 and the shield cases 21 and 26.

The circuit board 12 uses a printed circuit board in which conductive paths are formed on both sides of an insulating plate, and the conductive paths of the circuit board 12 include a power supply line PL connected to a power supply side (+side) of the vehicle and a ground line GL connected to a ground potential such as a vehicle body. A plurality of electronic components 14 are mounted on the conductive paths of the circuit board 12. The plurality of electronic components 14 include, for example, a field effect transistor (FET), a resistor, a diode, a coil, a capacitor, a microcomputer, or the like, and their terminals are connected to the conductive paths of the circuit board 12 by soldering or the like.

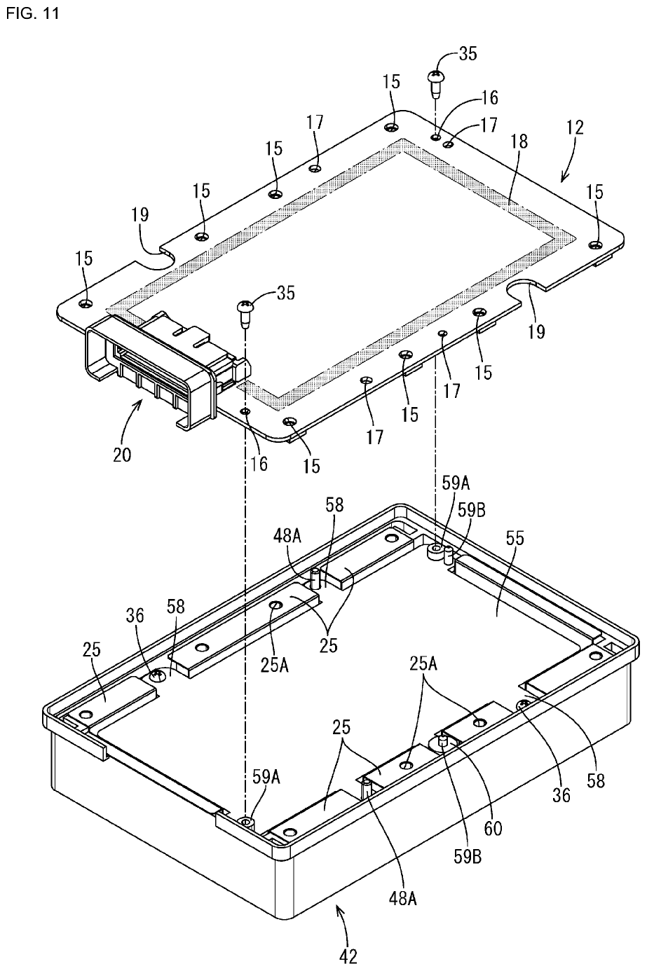

As illustrated in FIG. 11, the circuit board 12 is formed with a plurality of circular through-holes 15 to 17 and a plurality of clearance recesses 19 cut out from a peripheral edge of the circuit board 12. The plurality of through-holes 15 to 17 are provided at intervals along the peripheral edge of the circuit board 12, and the circuit board 12 has a plurality of first fastening holes 15 for fastening the shield cases 21 and 26 to the circuit board 12, a plurality of second fastening holes 16 for fastening the circuit board 12 to the frame 55, and a plurality of holding holes 17 through which holding pins 48A and 59B of the case unit 40 are inserted.

The first fastening holes 15 are provided along left and right side edges of the circuit board 12, and the first fastening members 31 are inserted through the first fastening holes 15. The first fastening members 31 have bolts 32 having a shaft portion 32A and a head portion 32B, and nuts 33, and the shaft portions 32A are inserted through the first fastening holes 15. The second fastening holes 16 are provided in the vicinity of front and rear edges of the circuit board 12, and second fastening members 35 are inserted through the second fastening holes 16. The second fastening members 35 are screws having a shaft portion 35A and a head portion 35B, and the shaft portions 35A are screwed to the frame 55. Among the plurality of holding holes 17, the holding pins 59B of the frame 55 are fitted into the holding holes 17 in the vicinity of a rear end edge of the circuit board 12, and the holding pins 48A of a first resin case 42 are fitted into the plurality of holding holes 17 in the vicinity of the left and right side edges of the circuit board 12. The clearance recesses 19 are provided on the left and right side edges of the circuit board 12, and are formed in a size that does not come into contact with the head portions 36B of the screws serving as the third fastening members 36 having shaft portions 36A and the head portions 36B.

Here, the circuit board 12 has a through-hole region 18 in which through-hole groups including a plurality of through-holes are arranged in a state of being electrically connected to each other. The through-hole region 18 extends in an annular shape along outer peripheral edge portions of the shield cases 21 and 26, and in the shield cases 21 and 26, at least a part of a first substrate fixing portion 25 and a second substrate fixing portion 29 fixed to the circuit board 12 overlaps the through-hole region 18.

Note that the circuit board 12 is not limited to the printed circuit board, and for example, the circuit board may be formed by overlaying a bus bar made of a metal plate material such as copper or a copper alloy on the printed circuit board.

A connector 20 is fixed to a front end of the circuit board 12. The connector 20 includes a housing that opens like a hood and a connector terminal that is fixed to the housing. The connector terminal is soldered to the conductive path of the circuit board 12.

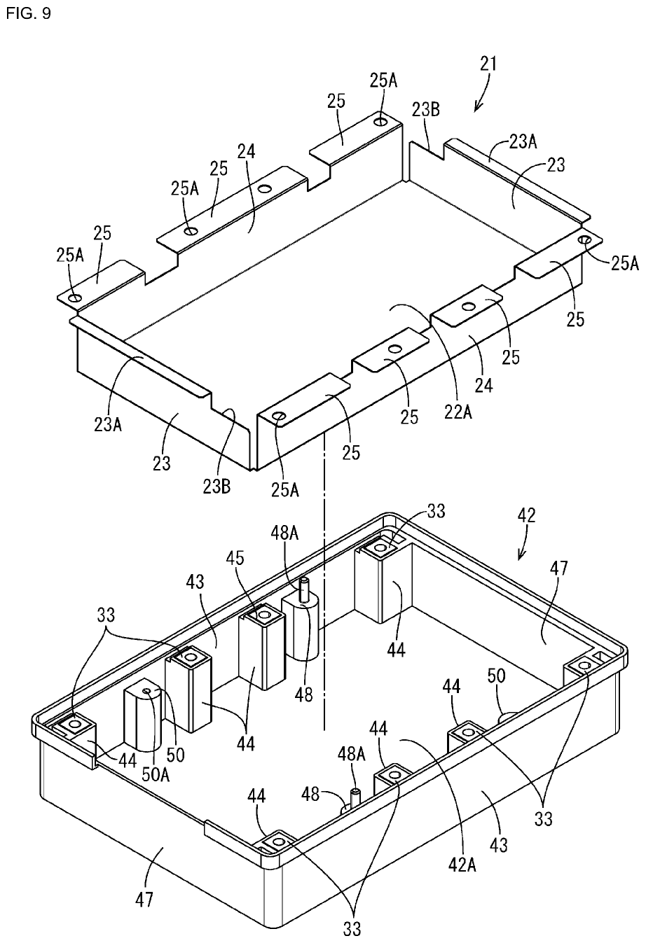

A first shield case 21 is made of a metal such as iron, stainless steel, or aluminum, and as illustrated in FIG. 9, includes a rectangular first facing portion 22A that is disposed facing a lower surface of the circuit board 12 at an interval, a pair of first end wall portions 23 extending upward from front and rear end edges of the first facing portion 22A, and a pair of first side wall portions 24 extending upward from both side edge portions of the first facing portion 22A.

The first end wall portion 23 is formed with an overhanging portion 23A that projects outward from a leading end portion thereof and a first cut-out portion 23B that is cut out from a leading end side thereof. The overhanging portion 23A overlaps with the lower surface (plate surface) of the circuit board 12. The first cut-out portion 23B is formed by cutting out a corner portion of the first end wall portion 23 in a rectangular shape, and a projecting piece 59 of the frame 55 can be led out to the outside.

A plurality of the first substrate fixing portions 25 that project outward and are fastened to the circuit board 12 are provided at upper ends (leading end portions) of the pair of first side wall portions 24. The plurality of first substrate fixing portions 25 overlap with the circuit board 12 so that at least one first substrate fixing portion 25 is connected to the ground line GL. Each first substrate fixing portion 25 is provided with one or more first shield fastening holes 25A through which the shaft portions 32A of the first fastening members 31 are inserted.

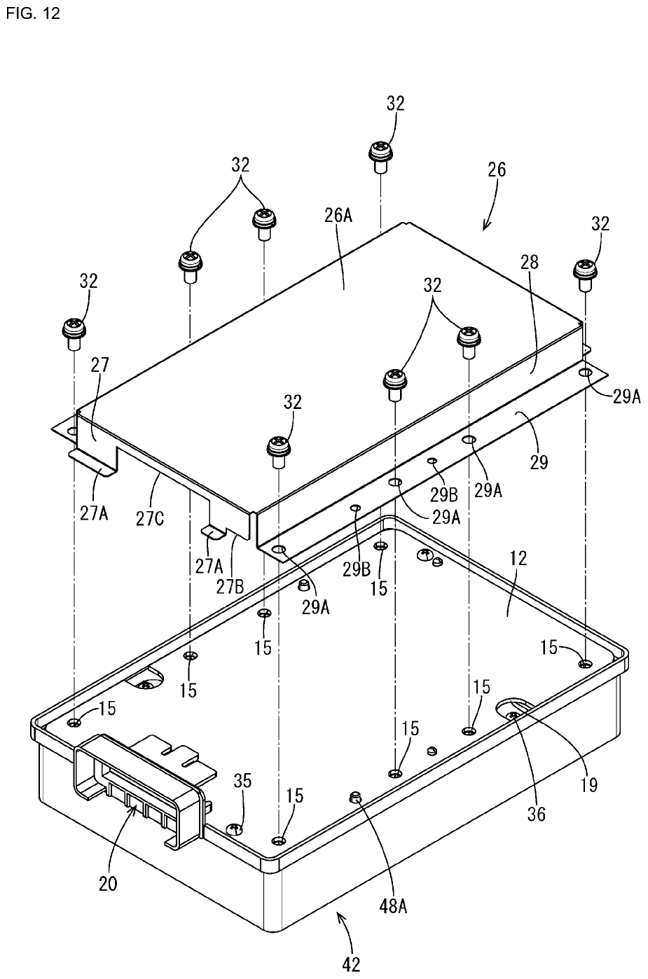

A second shield case 26 is made of a metal such as iron, stainless steel, or aluminum, and as illustrated in FIG. 12, includes a rectangular second facing portion 26A, a pair of second end wall portions 27 extending downward from front and rear end edges of the second facing portion 26A, and a plurality of second side wall portions 28 extending downward from left and right side end edges of the second facing portion 26A.

The second end wall portion 27 on a front side is formed with an overhang portion 27A that projects outward from a leading end portion thereof and overlaps with an upper surface of the circuit board 12, a second cut-out portion 27B that is cut out from a leading end side thereof, and a connector outlet 27C through which the connector 20 is led out to the outside. The second cut-out portion 27B is formed by cutting out a corner portion (corner portion on the circuit board 12 side) of the second end wall portion 27 in a rectangular shape so as not to come into contact with the head portion 35B of the second fastening member 35.

At lower ends of the pair of second side wall portions 28, second substrate fixing portions 29 that overlap with and are fastened to the circuit board 12 are provided. The second substrate fixing portions 29 extend from the lower ends of the plurality of second side wall portions 28 in a direction perpendicular to the second side wall portions 28, and a plurality of second shield fastening holes 29A through which the shaft portions 32A of the first fastening members 31 are inserted are provided at intervals in a front-rear direction of the second substrate fixing portions 29. Further, a second shield holding hole 29B through which the holding pin 59B of the frame 55 is inserted is formed through the second substrate fixing portion 29. The first shield case 21 and the second shield case 26 can be formed, for example, by punching a thin metal plate material into a developed shape with a press machine and bending it.

As illustrated in FIGS. 2 and 8, the case unit 40 has the resin cases 42 and 52 made of synthetic resin and the frame 55 made of synthetic resin fixed to the resin cases 42 and 52. The resin cases 42 and 52 include a box-shaped first resin case 42 that is disposed on a lower side and is open on an upper side, and a second resin case 52 that is disposed on the upper side and is fitted to the first resin case 42. As illustrated in FIG. 9, the first resin case 42 has a rectangular bottom surface portion 42A, a pair of side walls 43 rising from side edge portions of the bottom surface portion 42A, and a pair of connecting walls 47 that connect the ends of the pair of side walls 43.

On the side wall 43 side of the bottom surface portion 42A, a support portion 44 capable of supporting the substrate unit 11 from below, frame holding portions 48 capable of holding an attached position of the frame 55, and frame fixing portions 50 for fixing the frame 55 are provided projecting upward.

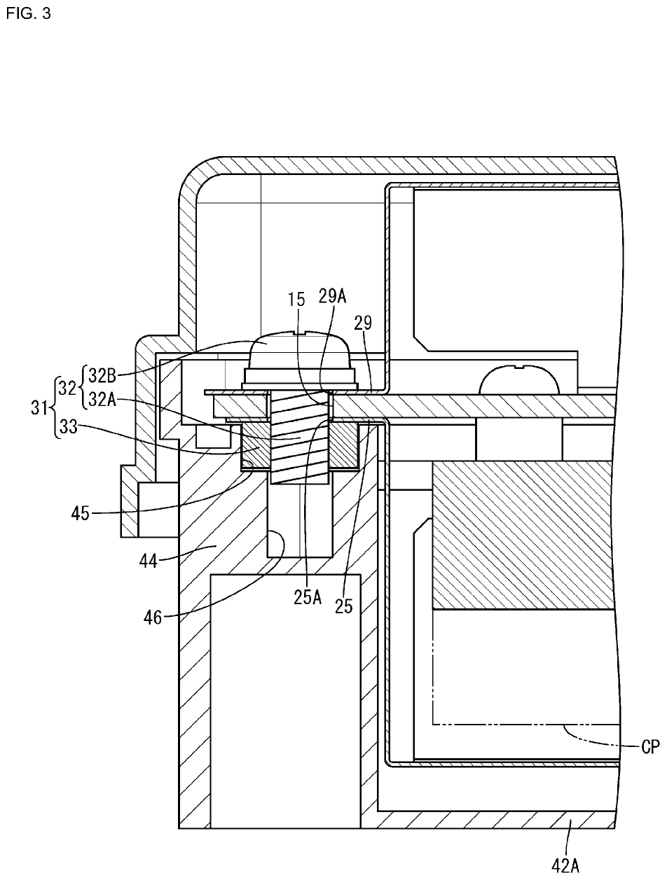

The support portion 44 projects upward in a columnar shape from the bottom surface portion 42A, and as illustrated in FIG. 3, a holding recess 45 capable of holding the nut 33 is formed at an upper end of the support portion 44. The holding recess 45 has an inner peripheral surface that fits onto an outer shape (outer periphery) of the nut 33, restricts rotation of the nut 33 when the bolt 32 is fastened, and has a clearance recess 46 formed on a bottom surface of the holding recess 45 for allowing clearance of the shaft portion 32A of the bolt 32.

As illustrated in FIG. 9, in the frame holding portions 48 and the frame fixing portions 50, the frame holding portions 48 are provided with the holding pins 48A projecting upward at leading end portions (upper ends) thereof, and the frame fixing portions 50 have screw holes 50A that can be screwed (bolted) and are formed at leading end portions (upper ends) thereof.

As illustrated in FIG. 8, the second resin case 52 includes a rectangular top surface portion 52A and a peripheral wall 53 extending downward from a peripheral edge portion of the top surface portion 52A. On the front side of the peripheral wall 53, a lead-out recess 53A that is cut out so that the connector 20 is led out is formed.

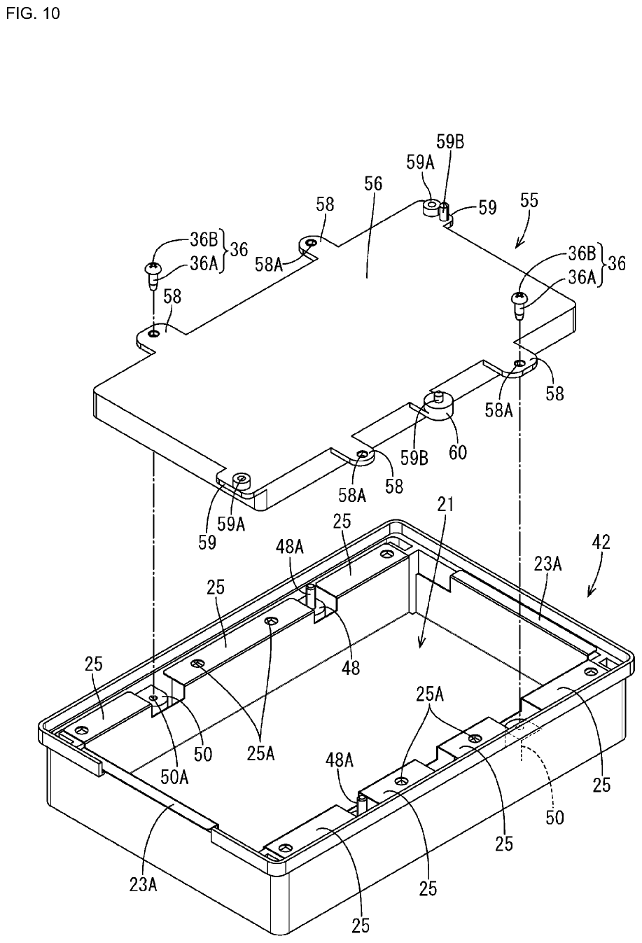

The frame 55 is made of synthetic resin, and as illustrated in FIG. 10, includes a plate-shaped main body 56 and a plurality of projecting pieces 58 to 60 projecting outward from a peripheral edge of the main body 56. The main body 56 holds a capacitor CP (an example of the “power storage element”) (see FIG. 2, the capacitor CP is omitted in FIG. 10 and the like). The main body 56 includes a capacitor holding portion (not shown) that can integrally hold a plurality of capacitors CP in an aligned state, and the capacitor unit can be formed by, for example, the frame 55. The capacitor CP has a columnar shape having a pair of positive and negative lead terminals, and can be, for example, an electric double layer capacitor, a lithium ion capacitor, or the like.

As illustrated in FIG. 10, the plurality of projecting pieces 58 to 60 include case fixing pieces 58 that project laterally from a side surface of the main body 56 and are fixed to the resin case 42, substrate fixing pieces 59 that project from front and rear edges of the main body 56 and are fixed to the circuit board 12, and a holding piece 60 that projects laterally from the side surface of the main body 56 and holds the circuit board 12.

A third fastening hole 58A through which the shaft portion 36A of the screw serving as the third fastening member 36 can be inserted is formed through the case fixing piece 58. A second fastening hole 59A through which the shaft portion 35A of the second fastening member 35 can be inserted is formed through the substrate fixing piece 59. The holding pin 59B projects from one of the substrate fixing pieces 59, side by side with the second fastening hole 59A. The holding pin 59B is inserted through the holding hole 17 of the circuit board 12 to hold a position in an XY direction of the circuit board 12.

Next, assembly of the electrical junction box 10 will be described.

As illustrated in FIG. 10, the first shield case 21 is fitted inside the first resin case 42, the frame 55 is attached to the first resin case 42, and the case fixing pieces 58 of the frame 55 are fastened to the frame fixing portions 50 of the first resin case 42 by the third fastening members 36. Further, the plurality of electronic components 14 and the connector 20 are mounted on the circuit board 12, and as illustrated in FIG. 11, the holding pins 59B of the frame 55 and the holding pins 48A of the first resin case 42 are fitted into the holding holes 17 of the circuit board 12, a peripheral edge portion of the circuit board 12 is caused to overlap with the first substrate fixing portions 25 of the first shield case 21, and the second fastening members 35 are inserted through the second fastening holes 16 of the circuit board 12 and screwed into the second fastening holes 59A of the frame 55.

Then, as illustrated in FIG. 12, the second shield case 26 is placed on the circuit board 12, and the second board fixing portion 29 is overlaid on the peripheral edge portion of the circuit board 12. Next, the shaft portions 32A of the bolts 32 serving as the first fastening members 31 are inserted through the first fastening holes 15 of the circuit board 12 and the shield fastening holes 25A and 29A of the shield cases 21 and 26, and are fastened to the nuts 33 of the holding recesses 45. Thus, the substrate unit 11 including the circuit board 12, the shield cases 21 and 26, and the first fastening members 31 is placed on the first resin case 42 (and the frame 55). In this state, since the nuts 33 (first fastening members 31) are allowed to move in a vertical direction in the holding recesses 45, the circuit board 12 and the shield cases 21 and 26 are not fastened (fixed) to the first resin case 42 by the first fastening members 31. On the other hand, since the frame 55 is fixed to both the circuit board 12 and the first resin case 42, the circuit board 12 is fixed to the first resin case 42 via the frame 55. Therefore, the relative positions of the substrate unit 11 and the frame 55 are fixed.

Then, the electrical junction box 10 is formed by placing the second resin case 52 from above the substrate unit 11 (FIG. 1).

According to the present embodiment, the following operations and effects are obtained.

The electrical junction box 10 includes: the substrate unit 11 having the circuit board 12 on which the conductive path including the ground line GL is formed, the shield case 21 (26) for covering the circuit board 12, and the first fastening member 31 for fastening the circuit board 12 and the shield cases 21 and 26; the case unit 40 having the resin cases 42 and 52 made of resin and the frame 55 fixed to the resin cases 42 and 52; and the second fastening member 35 for fastening the circuit board 12 in the substrate unit 11 and the case unit 40, in which the shield case 21 (26) is electrically connected to the ground line GL by fastening the circuit board 12 and the shield case 21 (26) with the first fastening member 31.

According to the present embodiment, in the substrate unit 11, by fastening the circuit board 12 and the shield cases 21 and 26 with the first fastening member 31, the ground line GL and the shield case 21 (26) can be electrically connected to each other while the shield cases 21 and 26 are fixed to the circuit board 12. Further, the relative positions of the substrate unit 11 and the case unit 40 can be fixed by fastening with the second fastening member 35. Thus, the fastening for electrical connection between the circuit board 12 and the shield cases 21 and 26 and the fastening for fixing the circuit board 12 to the case unit 40 can be performed with respective appropriate torques. Therefore, it is possible to provide the electrical junction box 10 fastened with an appropriate torque.

Further, the third fastening member 36 for fastening the frame 55 and the resin case 42 is provided, and the frame 55 holds the capacitor CP (power storage element).

When the frame 55 holds the capacitor CP, there is a concern that the weight of the capacitor CP may cause a problem due to stress generated, for example, at the portion fastened with the second fastening member 35. According to the present embodiment, since the capacitor CP is fixed to the resin cases 42 and 52 via the frame 55, it is possible to suppress the problem regarding the weight of the capacitor CP via the frame 55, and to fasten the frame 55 and the first resin case 42 by the third fastening member 36 with an appropriate torque.

Further, the shield cases 21 and 26 include the first shield case 21 for covering one plate surface of the circuit board 12 and the second shield case 26 for covering the other plate surface of the circuit board 12.

In this way, the influence of noise can be suppressed on both sides of the circuit board 12.

Further, the circuit board 12 has a through-hole region 18 in which a plurality of through-holes are electrically connected along an edge portion of the shield case 21 (26), and the through-hole region 18 is connected to the ground potential.

In this way, due to the through-hole group of the through-hole region 18, it is possible to shield a thick portion (between the first substrate fixing portion 25 and the second substrate fixing portion 29) of the circuit board 12 that is not shielded by the shield cases 21 and 26.

### Other Embodiments

The technique described in this specification is not limited to the embodiment described by the above description and the drawings, and for example, the following embodiments are also included in the technical scope of the technique described in this specification.

A configuration was used in which the first shield case 21 and the second shield case 26 are included, there is no limitation to this, and it is also possible to use a configuration in which only one of the first shield case 21 and the second shield case 26 is included.

A configuration was used in which the first resin case 42 and the second resin case 52 are included, but there is no limitation to this, and it is also possible to use a configuration in which the second resin case 52 is not included.

A configuration was used in which the circuit board 12 and the frame 55 are fastened to each other by the second fastening member 35, but there is no limitation to this, and it is also possible to use a configuration in which the circuit board 12 and the resin cases 42 and 52 are fastened to each other by the second fastening member 35.

A configuration was used in which the nut 33 serving as the first fastening member 31 is held in the holding recess 45 of the resin cases 42 and 52 at the time of assembly, but there is no limitation to this. For example, it is also possible to use a configuration in which the nut 33 is fixed to a hole edge portion of the first fastening hole 15 of the circuit board 12 by welding or the like.

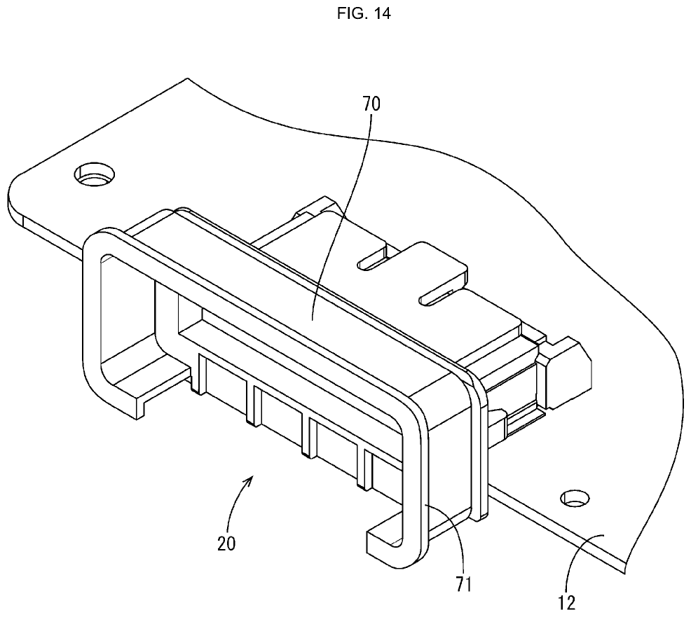

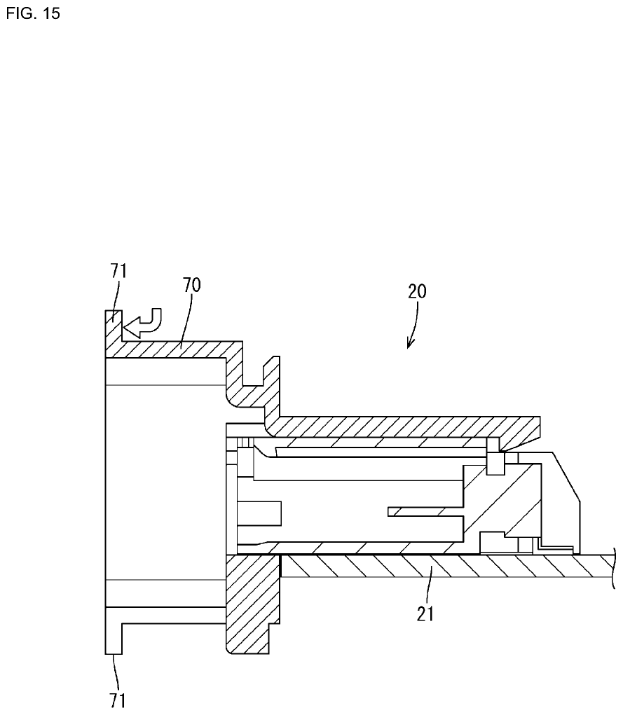

As illustrated in FIGS. 14 and 15, a flange portion 71 that projects outward may also be provided at a leading end portion of a hood portion 70 of a connector housing. In this way, since water from above (water in a direction of an arrow in FIG. 15) is blocked by the flange portion 71, it is possible to suppress intrusion of water into the inside of the connector housing.

A configuration was used in which the ground line GL is formed on both sides of the circuit board 12, but there is no limitation to this. For example, it is also possible to use a configuration in which the ground line GL is formed on one side of the circuit board 12, and one of the first shield case 21 and the second shield case 26 overlaps with the ground line GL and is electrically connected to the ground line GL.

1. An electrical junction box comprising:
a substrate unit having a circuit board on which a conductive path including a ground line is formed, a shield case for covering the circuit board, and a first fastening member for fastening the circuit board and the shield case;
a case unit having a resin case made of resin and a frame fixed to the resin case; and
a second fastening member for fastening the circuit board in the substrate unit and the case unit,
wherein the shield case is electrically connected to the ground line by fastening the circuit board and the shield case with the first fastening member.

2. The electrical junction box according to claim 1, further comprising:
a third fastening member for fastening the frame and the resin case,
wherein the frame holds a power storage element.

3. The electrical junction box according to claim 1, wherein the shield case includes a first shield case for covering one plate surface of the circuit board and a second shield case for covering the other plate surface of the circuit board.

4. The electrical junction box according to claim 1, wherein the circuit board has a through-hole region in which a plurality of through-holes are electrically connected along an edge portion of the shield case, and
the through-hole region is connected to a ground potential.

5. The electrical junction box according to claim 2, wherein the shield case includes a first shield case for covering one plate surface of the circuit board and a second shield case for covering the other plate surface of the circuit board.

6. The electrical junction box according to claim 2, wherein the circuit board has a through-hole region in which a plurality of through-holes are electrically connected along an edge portion of the shield case, and
the through-hole region is connected to a ground potential.

7. The electrical junction box according to claim 2, wherein the circuit board has a through-hole region in which a plurality of through-holes are electrically connected along an edge portion of the shield case, and
the through-hole region is connected to a ground potential.
